(19) United States
(12) Patent Application Publication
(10) Pub. No.: US 2011/0267740 A1
(43) Pub. Date: Nov. 3, 2011

(54) PACKAGING FOR ELECTROCHEMICALLY ACTIVE MATERIALS, DEVICES MADE THEREFROM, AND METHODS OF MAKING THE SAME

(76) Inventors: Shrisudersan Jayaraman, Painted Post, NY (US); James Robert Lim, Painted Post, NY (US); Patrick Aaron Parks, Elmira, NY (US); Todd Marshall Wetherill, Painted Post, NY (US)

(21) Appl. No.: 12/770,256

(22) Filed: Apr. 29, 2010

(51) Int. Cl. H01G 9/08; B23P 17/00; H05K 5/02

(52) U.S. Cl. 361/502; 174/50; 29/527.2

(57) ABSTRACT

The disclosure relates to packaging for electrochemically active materials comprising a housing comprising at least one active coating, devices made therefrom, and methods of making the same.

### FIELD OF THE DISCLOSURE

The disclosure relates to packaging for electrochemically active materials comprising a housing comprising at least one active coating, devices made therefrom, and methods of making the same.

### BACKGROUND

Electrochemically active devices, such as ultracapacitors or supercapacitors, typically comprise inert packaging or housing and, in some cases, the nature or configuration of the device results in ineffective or wasted electrochemically active material. For example, in the case of ultracapacitors, the device requires facing electrode surfaces (anode and cathode). Configurations such as spirals, jelly rolls, and stacks of the electrochemically active material may provide such facing surfaces over much of the device's volume. However, at the outer surface of such a configuration or outer diameter of a jelly roll set contained in an inert packaging, the outer electrode typically does not have a facing electrode. Thus, the electrochemically active material there may be ineffective in contributing to the activity of the capacitor, resulting in wasted material and space.

There exists a need to convert the inert packaging for electrochemically active materials to an element contributing to the activity of the device and/or to fully utilize the volume of the device. There also exists a need to convert ineffective portions of an electrochemically active material contained in a packaging to activity-contributing material. There also exists a need for methods of making packaging having such properties.

### SUMMARY

In accordance with the detailed description and various exemplary embodiments described herein, the disclosure relates to packaging for electrochemically active materials, devices made therefrom, and methods of making the same.

In various exemplary embodiments, the packaging for electrochemically active materials comprises a housing comprising at least one active coating. In further embodiments, the active coating may comprise at least one electrochemically active component, such as activated carbon. In further embodiments, the active coating may cover at least a portion of the interior surface of the housing, such as the surface of the housing configured to be in contact with or in contact with active surfaces of electrochemically active material.

In various exemplary embodiments, the disclosure also relates to packaging material for use in making packaging for electrochemically active materials comprising a substrate comprising at least one active coating. In further embodiments, the substrate may be aluminum sheeting and/or the active coating may comprise at least one electrochemically active component such as activated carbon.

In various exemplary embodiments, the disclosure also relates to electrochemically active devices made from the packaging for electrochemically active materials described herein. For example, in various embodiments the disclosure relates to electrochemically active devices comprising at least one packaging and at least one electrochemically active material, wherein the packaging comprises a housing comprising at least one active coating. In at least some exemplary embodiments, the devices may be energy storage or catalytic devices.

In various other exemplary embodiments, the disclosure relates to methods of making packaging for electrochemically active materials described herein. In various embodiments, the methods comprise applying at least one active coating to at least one surface of a housing.

### BRIEF DESCRIPTION OF THE DRAWINGS

The accompanying drawings are included to provide a further understanding of the invention, and are incorporated in and constitute a part of this specification. The drawings are not intended to be restrictive of the invention as claimed, but rather are provided to illustrate exemplary embodiments of the invention and, together with the description, serve to explain the principles of the invention.

FIG. 1 is a full view of packaging for electrochemically active materials according to at least one embodiment of the disclosure.

FIG. 2 is a cross-sectional view of the packaging for electrochemically active materials shown in FIG. 1 and according to at least one embodiment of the disclosure.

### DETAILED DESCRIPTION

It is to be understood that both the foregoing general description and the following detailed description are exemplary and explanatory only and are not restrictive of the invention, as claimed. Other embodiments will be apparent to those skilled in the art from consideration of the specification and practice of the embodiments disclosed herein. It is intended that the specification and examples be considered as exemplary only, with the true scope and spirit of the invention being indicated by the claims.

As used herein the use of “the,” “a,” or “an” means “at least one,” and should not be limited to “only one” unless explicitly indicated to the contrary. Thus, for example, the use of “the electrochemically active component” or “an electrochemically active component” is intended to mean at least one electrochemically active component.

In various exemplary embodiments, the packaging for electrochemically active materials comprises a housing comprising at least one active coating.

As used herein, the term “housing” is intended to mean a shaped body or vessel for receiving electrochemically active material. The housing comprises an interior surface, at least a portion of which is configured to contain electrochemically active material when in use, and an exterior surface, at least a portion of which is opposite from the interior surface and may be in contact with the environment when in use. The housing may, in some embodiments, also comprise a top surface or cover and/or a bottom surface or base. An interior surface of the housing linking a cover and a base is referred to herein as a wall. It is within the ability of one skilled in the art to determine an appropriate geometry or configuration for the housing. In various embodiments, the housing may, for example, be cylindrical, oblong or prismatic.

It is also within the ability of one skilled in the art to select an appropriate material for the housing, considering, for example, properties relevant to any particular embodiment, such as the corrosion resistance and/or conductivity of a given material. In various embodiments of the disclosure, the material for the housing may be chosen from aluminum, titanium, nickel, copper, tin, tungsten, molybdenum, steel, stainless steel, alloys, and a combination of metals with platings (i.e, gold or platinum). In at least one embodiment, the housing may be comprised of aluminum.

In various embodiments, the housing may further comprise at least one terminal The housing may be configured such that the terminal is connected to the electrochemically active material contained therein, such as electrically connected. For example, in various embodiments, the terminal may be connected to the anode or cathode of the electrochemically active material.

As used herein, the term “active coating,” and variations thereof, is intended to mean at least one layer of material comprising at least one electrochemically active component.

The electrochemically active component may be chosen from, but is not limited to, battery and ultracapacitor materials, for example activated carbon, graphite, pyrolized carbon, and hard carbon; additional battery materials, for example LiTiS₂, LiCoO₂, LiNi_{1-y}Co_{y}O₂, LiNi_{y}Mn_{y}Co_{1-2y}O₂, LiFePO₄, LiₓV₂O₅, LiNi_{1-y}Co_{y}O₂, LiMn₂O₄, LiNi_{1-y-z}Co_{y}Al_{z}O₂, LiNi_{1-y}Mn_{y}O₂, LiNi_{1-y}Mn_{1-y}Co_{2y}O₂, lithium metal, zinc metal; fuel cell and catalytic materials, for example platinum black and platinum metal; and biocatalytic (enzymatic and microbial) films and membranes.

In at least one embodiment, the electrochemically active component may be activated carbon, including but not limited to carbon that has been processed to make it extremely porous and, thus, to have a high specific surface area. For example, activated carbon may be characterized by a high BET specific surface area ranging from 300 to 2500 m²/g. Activated carbon for use in the active coating includes, but is not limited to, those marketed under the trade name Activated Carbon by Kuraray Chemical Company Ltd, of Osaka, Japan, Carbon Activated Corporation of Compton, Calif., and General Carbon Corporation of Paterson, N.J. Other suitable activated carbons are those disclosed in commonly owned U.S. application Ser. Nos. 12/335,044 and 61/297,469, the entire contents of which are incorporated herein by reference.

In various embodiments, the electrochemically active component may comprise from 0.1 to 100 wt % of the active coating, for example 1 to 99 wt %, 10-90 wt %, such as 85 wt %.

In various embodiments, the active coating may further comprise at least one binding and/or adhesion agent. As used herein, binding and/or adhesion agents include, but are not limited to, polytetrafluoroethylene (PTFE), polyvinylidene fluoride (PVDF), polyvinylpyrrolidone (PVP), polyvinyl acetate (PVA), polyethylene oxide (PEO), polypropylene, polyethylene, polyurethane, polyacrylates, and other organic (yet chemically and electrochemically inert) binders.

In various embodiments, the binding and/or adhesion agent may comprise from 0.01 to 50 wt % of the active coating, for example 0.1 to 49 wt %, and 1 to 40 wt %, such as 10 wt %.

In various embodiments, the active coating may further comprise at least one conduction enhancing agent, such as carbon black; metallic nanotubes, rods, and wires; carbon nanotubes, rods, scrolls, and wires; graphene scrolls and sheets; graphite (natural or synthetic); conductive nanoparticles; and conductive polymers. The conduction enhancing agent may comprise from 0.01 to 50 wt % of the active coating, for example 0.1 to 49 wt %, 1 to 45 wt %, such as 5 wt %.

In at least one embodiment, the conduction enhancing agent may be carbon black. Carbon black includes forms of amorphous carbon with a high specific surface area. For example, carbon black may be characterized by a relatively high BET specific surface area, for example ranging from 25 m²/g to 2000 m²/g, such as ranging from 200 m²/g to 1800 m²/g and ranging from 1400 m²/g to 1600 m²/g. Carbon blacks useful in the active coating include, but are not limited to, those marketed under the trade name BLACK PEARLS® 2000 by Cabot Corporation of Boston, Mass., VULCAN® XC 72 by Cabot Corporation of Boston, Mass., and PRINTEX® L6 by Evonik of Essen, Germany.

The thickness of the active coating may range from 100 nm to 5 mm, for example 0.25 μm to 200 μm, or 10 μm to 100 μm. In various embodiments, the active coating may be uniform in thickness and in others it may not be uniform in thickness.

It is within the ability of one skilled in the art to determine what portions of the housing to coat with the active coating, which may include, for example, consideration of the desired loading of electrochemically active component, the surface areas that will contact the electrochemically active material, welding surfaces, and the method for applying the active coating. In various embodiments, for example, the active coating may cover at least a portion of the interior surface of the housing. In a further embodiment, the active coating may cover all or substantially all of the interior surface of the housing. In additional embodiments, the active coating may cover all or substantially all of the interior sides or walls of the housing, but not the top and/or bottom surfaces. In another embodiment, the active coating may not cover housing surfaces for use in welding, such as for example upper and/or lower portions of the housing walls, i.e., those portions closest to the top and/or bottom surfaces. For example, in at least one exemplary embodiment, the walls of the housing may be coated except for the upper and/or lower approximately 5-10% of the wall surfaces to allow for welding. In various other embodiments of the disclosure, the active coating may cover a portion of the surface of the housing configured to be in contact with or in contact with active surfaces of the electrochemically active material, and in further embodiments, it may cover all or substantially all of the surfaces of the housing configured to be in contact with or in contact with active surfaces of the electrochemically active material. In further embodiments, the at least one active coating may cover the interior surface in any pattern, such as ribbed patterns, diamond patterns, cross-hatched patterns, dot containing patterns, dimple containing patterns, zig-zag patterns, spiral patterns, circular patterns, square patterns, triangular patterns, hexagonal patterns, rectangular patterns, and combinations thereof. Additionally, a random or irregular pattern can be created, for example by blowing air along the surface of a recently applied active coating.

In various embodiments, the packaging may comprise at least two layers of active coating. In further embodiments, two layers of active coating may be of the same or different compositions, may comprise the same or different electrochemically active component, and/or may coat the same and/or different surfaces of the housing.

The packaging of the disclosure may further comprise at least one pre-coating. As used herein, the term “pre-coating,” and variations thereof, is intended to mean a layer of material comprising at least one adhesion agent, wherein said layer is intended to be applied between the housing and the active coating.

The adhesion agent may be chosen from, but is not limited to, polytetrafluoroethylene (PTFE), polyvinylidene fluoride (PVDF), polyvinylpyrrolidone (PVP), polyvinyl acetate (PVA), polyethylene oxide (PEO), polypropylene, polyethylene, polyurethane, polyacrylates, and other organic (yet chemically and electrochemically inert) adhesives. In at least one embodiment, the adhesion agent may be a combination of PVP and polyacrylates.

In various embodiments, the adhesion agent may comprise from 0.01 to 85 wt % of the pre-coating, for example 0.1 to 84 wt %, 1 to 80 wt %, 5 to 75 wt %, such as 10 wt %.

In various embodiments, the pre-coating may further comprise at least one conduction enhancing agent, such as carbon black; metallic nanotubes, rods and wires; carbon nanotubes, rods, scrolls, and wires; graphene, scrolls and sheets; graphite (natural and synthetic); conductive nanoparticles; conductive polymers; and combinations thereof. The conduction enhancing agent may comprise from 0.01 to 99.99 wt % of the pre-coating, for example 0.1 to 99.9 wt %, 1 to 99 wt %, and 10 to 90 wt %.

The thickness of the pre-coating may range from 100 nm to 25 μm, for example 500 nm to 10 μm, such as 1 μm. In various embodiments, the pre-coating may be uniform in thickness, and in other embodiments it may not be uniform in thickness.

It is within the ability of one skilled in the art to determine what portions of the housing to coat with the pre-coating, which may include consideration of the desired location for the active coating and the method for applying the pre-coating. In various embodiments, for example, the pre-coating may cover at least a portion of the interior surface of the housing. In a further embodiment, the pre-coating may cover all or substantially all of the interior surface of the housing. In additional embodiments, the pre-coating may cover all or substantially all of the interior sides or walls of the housing, but not the top and/or bottom surfaces. In another embodiment, the pre-coating may not cover housing surfaces for use in welding, such as for example the upper and/or lower portions of the housing walls, i.e., those portions closest to the top and/or bottom surfaces. For example, in at least one embodiment, the walls of the housing may be coated except for the upper and/or lower approximately 5-10% of the wall surfaces to allow for welding. In various other embodiments of the disclosure, the pre-coating may cover a portion of the surface of the housing configured to be in contact with or in contact with active surfaces of the electrochemically active material, and in further embodiments, it may cover all or substantially all of the surface of the housing configured to be in contact with or in contact with active surfaces of the electrochemically active material. In further embodiments, the pre-coating may cover the interior surface in any pattern, such as ribbed patterns, diamond patterns, cross-hatched patterns, dot containing patterns, dimple containing patterns, zig-zag patterns, spiral patterns, circular patterns, square patterns, triangular patterns, hexagonal patterns, rectangular patterns, and combinations thereof. Additionally, a random or irregular pattern can be created, for example by blowing air along the surface of a recently applied pre-coating.

In at least one embodiment, the pre-coating may cover all surfaces of the housing where the active coating is applied.

The packaging of the disclosure may also comprise at least one inert coating. As used herein, the term “inert coating” and variations thereof, is intended to mean a layer of material other than active coatings and pre-coatings and may include, for example, a coating to protect the housing from corrosion, a coating to facilitate transfer of heat from the packaging interior to the exterior, a coating for forming a hermetic safety seal, and a coating to absorb moisture within the device. Inert coatings include, but are not limited to, parylene coatings, such as those marketed by Specialty Coating Systems of Indianapolis, Ind.

The inert coating may be applied directly to the surface of the housing, i.e., before the active coating and/or pre-coating, between the pre-coating and active coating, and variations thereof.

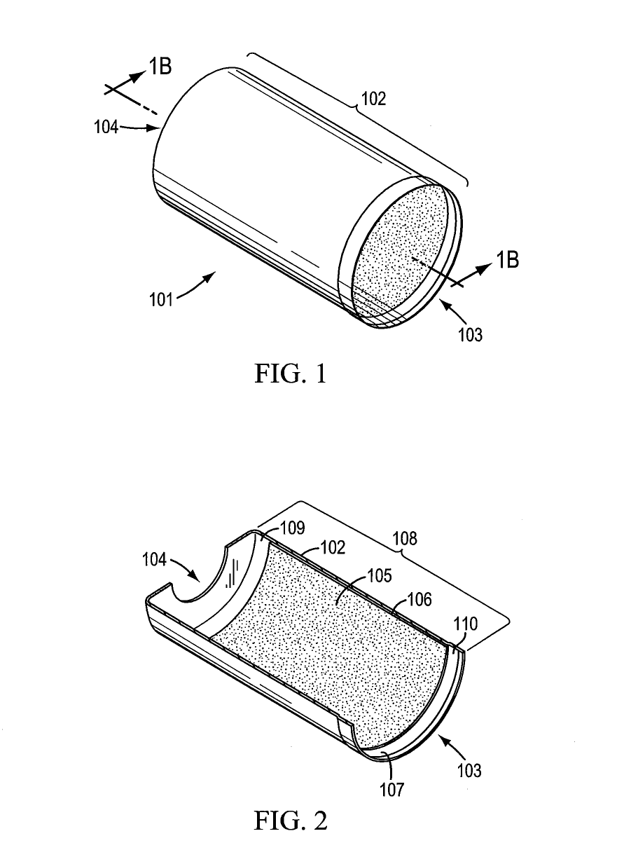

FIGS. 1 and 2 show exemplary packaging for electrochemically active materials according to at least one embodiment of the disclosure. FIG. 1 depicts a cylindrical packaging 101 with walls 102 and an open bottom 103 and partial top 104. FIG. 2 is a cross-section of the packaging 101 and depicts an active coating 105 and a pre-coating 106 on the interior surface 107 of the housing 108. FIG. 2 also depicts an upper portion 109 and lower portion 110 of the housing wall that has not been coated, such as to allow for welding.

In various exemplary embodiments, the disclosure also relates to packaging material for use in making packaging for electrochemically active materials comprising a substrate comprising at least one active coating.

As used herein, the term “substrate” is intended to mean a material capable of being shaped into housing for packaging electrochemically active materials as described herein. A material for the substrate may, for example, be chosen from aluminum, titanium, nickel, copper, tin, tungsten, molybdenum, steel, stainless steel, alloys and a combination of metals with platings (i.e, gold or platinum). In at least one embodiment, the substrate may be comprised of aluminum sheeting.

As described above, the active coating is a layer of material comprising at least one electrochemically active component. In at least one embodiment, the electrochemically active component may be activated carbon, such as those described above.

It is within the ability of one skilled in the art to determine what portions of the substrate to coat with the active coating, which may include consideration of factors such as, for example, the desired loading of electrochemically active component, the surfaces that will contact the electrochemically active material when shaped into a housing, welding surfaces, and the method for applying the active coating. In various embodiments, for example, the active coating may cover at least a portion of one side of the substrate. In a further embodiment, the active coating may cover all or substantially all of one side of the substrate. In additional embodiments, the active coating may cover all or substantially all of one side of the substrate and not at least a portion of the substrate at the edges. In another embodiment, the active coating my not cover substrate surfaces for use in welding, such as for example the substrate surface at the edges. For example, in at least one embodiment, one side of the substrate may be coated except for approximately 5-10% border at the edges. In various other embodiments of the disclosure, the active coating may cover a portion of the surface of the substrate intended to be contact with active surfaces of the electrochemically active material when shaped into a housing, and in further embodiments, it may cover all or substantially all of the surface of the substrate intended to be contact with active surfaces of the electrochemically active material when shaped into a housing. In further embodiments, the active coating may cover the substrate in any pattern, such as ribbed patterns, diamond patterns, cross-hatched patterns, dot containing patterns, dimple containing patterns, zig-zag patterns, spiral patterns, circular patterns, square patterns, triangular patterns, hexagonal patterns, rectangular patterns, and combinations thereof. Additionally, a random or irregular pattern can be created, for example by blowing air along the surface of a recently applied active coating.

The thickness of the active coating may range from 100 nm to 5 mm, for example 0.25 μm to 200 μm, or 10 μm to 100 μm. In various embodiments, the active coating may be uniform in thickness and in others it may not be uniform in thickness.

In various embodiments, the substrate may further comprise at least one pre-coating as described herein. In at least one embodiment, the pre-coating may further comprise at least one conduction enhancing agent, such as carbon black.

It is within the ability of one skilled in the art to determine what portions of the substrate to coat with the pre-coating, which may include factors such as, for example, consideration of the desired location for the active coating and the method for applying the pre-coating. In various embodiments, for example, the pre-coating may cover at least a portion of one side of the substrate. In a further embodiment, the pre-coating may cover all or substantially all of the surface of one side of the substrate. In additional embodiments, the pre-coating may not cover substrate surfaces to be used in welding, such as for example the edges of the substrate. For example, in at least one embodiment, one side of the substrate may be coated with the pre-coating except for approximately 5-10% border around the edges. In various other embodiments of the disclosure, the pre-coating may cover a portion of the surface of the substrate that are intended to contact active surfaces of the electrochemically active material when shaped into a housing, and in further embodiments, it may cover all or substantially all of the surface of the substrate intended to be in contact with active surfaces of the electrochemically active material when shaped into a housing. In at least one embodiment, the at least one pre-coating covers all surfaces of the substrate where the at least one active coating is applied. In further embodiments, the pre-coating may cover the substrate in any pattern, such as ribbed patterns, diamond patterns, cross-hatched patterns, dot containing patterns, dimple containing patterns, zig-zag patterns, spiral patterns, circular patterns, square patterns, triangular patterns, hexagonal patterns, rectangular patterns, and combinations thereof. Additionally, a random or irregular pattern can be created, for example by blowing air along the surface of a recently applied pre-coating.

In various embodiments, the substrate may further comprise at least one inert coating as described herein. The inert coating may be applied directly to the substrate, i.e., before the active coating and/or pre-coating, between the pre-coating and active coating, and variations thereof.

The thickness of the pre-coating may range from 100 nm to 25 μm, for example 500 nm to 10 μm. In various embodiments, the pre-coating may be uniform in thickness and in others it may not be uniform in thickness.

In various other exemplary embodiments, the disclosure relates to methods of making the packaging for electrochemically active materials described herein. More specifically, the methods comprise applying at least one active coating to at least one surface of a substrate or housing. It is within the ability of one skilled in the art to select an appropriate method for applying the active coating, including for example, gravure coating methods, slot die coating methods, spray coating methods, screen-printing methods, ink-jet printing methods, tape-casting methods, dip-coating methods, curtain coating, slide-bead coating, slip coating, common roll coating, or a combination thereof.

In various exemplary embodiments, portions of the substrate or housing surface may optionally be masked and then the substrate or housing may be dipped in the active coating material comprising an electrochemically active component or the active coating may be applied with a roller or sprayed on at least one surface of the substrate or housing. In other embodiments, a preform or sheet of the active coating may be rolled or pressed onto to the substrate or housing under pressure and/or heat.

In additional embodiments, the methods may further comprise applying at least one pre-coating before application of the active coating. It is also within the ability of one skilled in the art to select an appropriate method for applying the pre-coating, including for example, gravure coating methods, slot die coating methods, spray coating methods, screen-printing methods, ink-jet printing methods, tape-casting methods, dip-coating methods, curtain coating, slide-bead coating, slip coating, common roll coating, and a combination thereof.

In various embodiments, where the active coating is applied to a substrate, the methods may further comprise shaping the substrate after application of the active coating. For example, in at least one embodiment, the substrate may be shaped or rolled into a cylinder.

In various exemplary embodiments, the disclosure also relates to electrochemically active devices made from the packaging for electrochemically active materials described herein. More specifically, it relates to electrochemically active devices comprising at least one packaging and at least one electrochemically active material, wherein the at least one packaging comprises housing comprising at least one active coating.

As used herein, the term “electrochemically active devices,” and variations thereof, is intended to mean devices for electrochemical storage, electrochemical synthesis or catalysis. These devices include, for example, capacitors (including electrochemical double layer capacitors), primary and secondary batteries, fuel cells, and other hybrids. In at least one embodiment, the electrochemical device is a capacitor, such as an ultracapacitor.

As used herein, the term “electrochemically active material,” and variations thereof, is intended to mean electrochemical energy storage (non-faradic and faradic) materials and oxidative/reductive catalytic materials. Electrochemically active materials may be incorporated in, for example, electrodes, such as high surface area carbon coated on two sides of an aluminum foil; cathode materials, such as LiCoO₂; anode materials, such as graphite; catalytic platinum for oxygen reduction; and biocatalytic membranes, such as glucose oxidase embedded enzymes within a polymer matrix.

It is within the ability of one skilled in the art to configure the electrochemically active material in a manner appropriate for use in the packaging. For example, the electrochemically active material may be rolled into a spiral wrap or jelly-roll for placement in a cylindrical or oblong packaging or the material may be stacked for placement in a prismatic packaging.

At least one embodiment of the disclosure relates to ultracapacitor devices wherein the electrochemically active material may be incorporated in two electrodes comprising activated carbon coated on two sides of an aluminum foil, separated by two porous separator papers, and wrapped into a jelly roll.

In various embodiments of the disclosure, the electrochemically active coating may increase the effective amount of electrochemically active component in a given device. As used herein, the term “effective,” “effective amount,” and variations thereof are intended to include the electrochemically active material that contributes to the activity of the device; whereas “ineffective,” “ineffective amount,” “unutilized,” “unutilized amount,” and variations thereof are intended to include the electrochemically active material that does not contribute to the activity of the device. For example, the outer surface of a jelly roll of electrochemically active material may be ineffective when in an inert packaging; whereas, it may be effective when in packaging of the disclosure.

The effective amount of electrochemically active component in an electrochemically active device of the disclosure may be increased by at least 0.5 wt % relative to a comparable device outside the scope of the disclosure, for example at least 1 wt %, at least 2 wt %, at least 4 wt %, or at least 6 wt %. The increased effective amount may be comprised of both electrochemically active component in the active coating and electrochemically active component on the outer surface of the electrochemically active material that was previously ineffective or unutilized.

In further embodiments, increased effective amounts of electrochemically active component may result in increased activity for the device, such as increased energy storage capacity, as compared to a device without the packaging disclosed herein. In additional embodiments, the increased activity may be achieved within the same footprint or volume as a comparable device without the packaging described herein, thereby improving the volumetric efficiency of the device.

The packaging of the disclosure may also protect the housing from reactions which may degrade the housing and/or otherwise adversely affect the device performance or long term stability.

The packaging of the disclosure may also facilitate heat transfer from the interior of the packaging, such as that generated by cycling of an electrochemical storage device, to the exterior of the device, such as the environment or heat sinking.

Unless otherwise indicated, all numbers used in the specification and claims are to be understood as being modified in all instances by the term “about,” whether or not so stated. It should also be understood that the precise numerical values used in the specification and claims form additional embodiments of the invention. Efforts have been made to ensure the accuracy of the numerical values disclosed herein. Any measured numerical value, however, can inherently contain certain errors resulting from the standard deviation found in its respective measuring technique.

Other embodiments of the invention will be apparent to those skilled in the art from consideration of the specification and practice of the invention disclosed herein. It is intended that the specification be considered as exemplary only, with a true scope and spirit of the invention being indicated by the claims.

What is claimed is:

1. Packaging for an electrochemically active material, said packaging comprising a housing comprising at least one active coating.

2. The packaging of claim 1, wherein the at least one active coating comprises at least one activated carbon.

3. The packaging of claim 1, wherein the at least one active coating further comprises at least one binder and/or adhesion agent.

4. The packaging of claim 1, wherein the at least one active coating further comprises at least one conduction enhancing agent.

5. The packaging of claim 1, wherein the at least one active coating further comprises at least one conduction enhancing agent chosen from carbon blacks.

6. The packaging of claim 1, wherein the packaging further comprises at least one pre-coating.

7. The packaging of claim 1, wherein the packaging further comprises at least one pre-coating comprising at least one conduction enhancing agent.

8. The packaging of claim 1, wherein the packaging further comprises at least one pre-coating comprising at least one conduction enhancing agent chosen from carbon blacks.

9. The packaging of claim 1, wherein the at least one active coating covers at least a portion of an interior surface of the housing.

10. The packaging of claim 1, wherein the at least one active coating covers all or substantially all of an interior surface of the housing.

11. The packaging of claim 1, wherein the at least one active coating substantially covers a surface of the housing that is configured to be in contact with active surfaces of the electrochemically active material.

12. The packaging of claim 1, wherein the housing is cylindrical, oblong or prismatic in shape.

13. Packaging material for use in making packaging for electrochemically active materials comprising a substrate comprising at least one active coating.

14. The packaging material of claim 13, wherein the at least one active coating comprises at least one activated carbon.

15. The packaging of claim 13, wherein the packaging further comprises at least one pre-coating.

16. The packaging of claim 13, wherein the packaging further comprises at least one pre-coating comprising at least one conduction enhancing agent chosen from carbon blacks.

17. The packaging of claim 13, wherein the at least one active coating covers at least a portion of one side of the substrate.

18. The packaging of claim 13, wherein the at least one active coating covers all or substantially all of one side of the substrate.

19. An electrochemically active device comprising at least one packaging and at least one electrochemically active material;
wherein the at least one packaging comprises a housing comprising at least one active coating.

20. The electrochemically active device of claim 19, wherein the at least one electrochemically active material is incorporated in a double layer capacitor.

21. The electrochemically active device of claim 19, wherein the at least one electrochemically active material is incorporated in a double layer capacitor shaped like a jelly roll.

22. The electrochemically active device of claim 19, wherein the at least one active coating comprises at least one activated carbon.

23. The electrochemically active device of claim 19, wherein the at least one active coating further comprises at least one binder and/or adhesion agent.

24. The electrochemically active device of claim 19, wherein the packaging further comprises at least one pre-coating.

25. The electrochemically active device of claim 19, wherein the at least one active coating covers at least a portion of an interior of the housing.

26. The electrochemically active device of claim 19, wherein the at least one active coating substantially covers a surface of the housing in contact with active surfaces of the electrochemically active material.

27. The electrochemical storage device of claim 19, wherein the at least one packaging is cylindrical, oblong, or prismatic in shape.

28. The electrochemically active device of claim 19, wherein the at least one packaging further comprises at least one terminal.

29. The electrochemically active device of claim 19, wherein the at least one active coating increases the amount of effective electrochemically active component in the device by at least 0.5 wt %.

30. A method of making packaging for an electrochemically active material, wherein the method comprises:
applying at least one active coating to at least one surface of a housing or substrate using a method chosen from dipping the housing or the at least one active coating onto at least substrate, pressing a sheet or preform of one surface of the housing or substrate, and spraying at least one surface of the housing or substrate.

31. The method according to claim 30, wherein the at least one active coating is applied to a substrate and further comprising shaping the substrate after application of the at least one active coating.

32. The method according to claim 30, further comprising shaping a substrate to form at least one housing before application of the at least one active coating.

33. The method according to claim 30, further comprising applying at least one pre-coating before application of the at least one active coating.
